(19) United States
(12) Patent Application Publication
(10) Pub. No.: US 2018/0044785 A1
(43) Pub. Date: Feb. 15, 2018

(54) COATING DEVICE WITH MOVING TARGET AND COATING METHOD

(71) Applicants: BOE TECHNOLOGY GROUP CO., LTD., Beijing (CN); HEFEI XINSHENG OPTOELECTRONICS TECHNOLOGY CO., LTD, Hefei, Anhui (CN)

(72) Inventors: Guoping QIAN, Beijing (CN); Yangkun JING, Beijing (CN); Chengye WU, Beijing (CN); Bei WANG, Beijing (CN); Yu JI, Beijing (CN)

(21) Appl. No.: 15/552,184

(22) PCT Filed: Jan. 3, 2017
(86) PCT No.: PCT/CN2017/000038

§ 371 Date: Aug. 18, 2017

(30) Foreign Application Priority Data
Jan. 26, 2016 (CN) 201610053369.8

(51) Int. Cl. C23C 14/54; C23C 14/35

(52) U.S. Cl. CPC C23C 14/541; C23C 14/542; C23C 14/35; H05B 2203/032; H01L 51/001

(57) ABSTRACT

A mobile target coating device includes: a target source; a target source carrier section configured to carry and drive the target source to move; an infrared temperature detecting section configured to detect a temperature of a surface of the target source; an infrared heating section configured to heat the target source; a control section configured to receive a detection signal of the infrared temperature detecting section and determine whether the temperature of the surface of the target source is uniform or not; the control section is further configured to control the infrared heating section to heat a portion having a lower temperature of the surface of the target source and to stop heating after the temperature of the surface of the target source becomes uniform. A coating method using a mobile target coating device is also disclosed.

### TECHNICAL FIELD

The present disclosure relates to a mobile target coating device (or coating device with moving target) and coating method, and especially relates to a mobile target coating device comprising an infrared temperature detecting section and an infrared heating section as well as the coating method.

### BACKGROUND

Organic light-emitting diode (OLED) display devices have advantages, such as self-illumination, high contrast, thin thickness, wide viewing angle, fast response, availability for flexible panels, wide working temperature range, simple construction and process and etc., and have become one of the mainstream developments of the current flat display technology. In the process of preparing organic light emitting devices, the use of mobile targets for coating is a way to improve the target utilization rate.

### SUMMARY

An embodiment of the present disclosure provides a mobile target coating device, comprising: a target source; a target source carrier section configured to carry and drive the target source to move; an infrared temperature detecting section configured to detect a temperature of a surface of the target source; an infrared heating section configured to heat the target source; a control section configured to receive a detection signal of the infrared temperature detecting section and determine whether the temperature of the surface of the target source is uniform or not; the control section is further configured to control the infrared heating section to heat a portion having a lower temperature of the surface of the target source and to stop heating after the temperature of the surface of the target source becomes uniform.

As for the mobile target coating device according to an embodiment of the disclosure, for example, the infrared temperature detecting section and the infrared heating section are connected to the target source carrier section, and the infrared temperature detecting section and the infrared heating section can move in synchronism with the target source carrier section.

As for the mobile target coating device according to an embodiment of the disclosure, for example, the surface of the target source is essentially parallel to a surface of the infrared heating section; normal projections of the target source and the infrared heating section on a same plane at least partially overlap with each other.

As for the mobile target coating device according to an embodiment of the disclosure, for example, an area size of the target source is less than or equal to an area size of the infrared heating section.

As for the mobile target coating device according to an embodiment of the disclosure, for example, the infrared temperature detecting section is located between the surface of the target source and a surface of the infrared heating section.

As for the mobile target coating device according to an embodiment of the disclosure, for example, the surface of the target source is in a unity.

As for the mobile target coating device according to an embodiment of the disclosure, for example, the surface of the target source is composed of a plurality of discrete sub-target sources.

As for the mobile target coating device according to an embodiment of the disclosure, for example, the plurality of discrete sub-target sources are arranged in an annular arrangement.

As for the mobile target coating device according to an embodiment of the disclosure, for example, the infrared heating section comprises a plurality of infrared heating radiating sheets, the control section is further configured to, in a case where the control section determines that a temperature of a portion of the surface of the target source is lower than a temperature of other portions and a temperature difference value exceeds a pre-set value, actuate an infrared heating radiating sheet or infrared heating radiating sheets opposite to the surface of the target source at the portion having the lower temperature, and to heat the surface of the target source at the portion having the lower temperature until the temperature of the surface of the target source becomes uniform and stop heating.

As for the mobile target coating device according to an embodiment of the disclosure, for example, each of the infrared heating radiating sheets comprises a radiation converging structure.

As for the mobile target coating device according to an embodiment of the disclosure, for example, the infrared heating section comprises one infrared heating radiating sheet, in a case where the control section determines that a temperature of a portion of the surface of the target source is lower than a temperature of other portions and a temperature difference value exceeds a pre-set value, the control section controls the infrared heating radiating sheet to turn on and heat the surface of the target source at the portion having the lower temperature until the temperature of the surface of the target source becomes uniform and stop heating.

As for the mobile target coating device according to an embodiment of the disclosure, for example, the target source carrier section comprises a guide rail and a target source support member, and the target source support member is configured to move on the guide rail when the target source is required to move.

As for the mobile target coating device according to an embodiment of the disclosure, for example, the guide rail is a maglev track, and the maglev track and the target source support member are configured to generate an electromagnetic repulsive force therebetween so as to hold up the target source support member into a suspended state.

As for the mobile target coating device according to an embodiment of the disclosure, for example, the guide rail comprises an air-cushion track on which a plurality of air holes are provided facing the target source support member, the plurality of air holes on the air-cushion track are configured to eject high-speed gas flows so as to hold up the target source support member into a suspended state.

As for the mobile target coating device according to an embodiment of the disclosure, for example, the target source is arranged essentially parallel to the ground.

As for the mobile target coating device according to an embodiment of the disclosure, for example, the infrared heating section is arranged above the target source.

As for the mobile target coating device according to an embodiment of the disclosure, for example, the infrared heating section is arranged essentially parallel to the ground.

As for the mobile target coating device according to an embodiment of the disclosure, for example, the target source is arranged above the target source.

As for the mobile target coating device according to an embodiment of the disclosure, for example, the target source and the infrared heating section are arranged essentially perpendicular to the ground.

As for the mobile target coating device according to an embodiment of the disclosure, for example, the infrared temperature detecting section comprises an infrared camera.

An embodiment of the present disclosure provides a coating method using a mobile target coating device, the mobile target coating device comprising a target source, a target source carrier section, an infrared temperature detecting section for detecting a temperature of a surface of the target source, an infrared heating section for heating the target source, and a control section, wherein the target source carrier section carries the target source and can drive the target source to move freely in three dimensional directions, and the infrared temperature detecting section and the infrared heating section are in signal communication with the control section, the method comprising: the control section receiving a detection signal from the infrared temperature detecting section, and determining whether the temperature of the surface of the target source is uniform or not, in a case where the control section determines that a temperature of a portion of the surface of the target source is lower than a temperature of other portions and a temperature difference value exceeds a pre-set value, the control section controls the infrared heating section to heat the surface of the target source at the portion having the lower temperature until the temperature of the surface of the target source becomes uniform and stop heating.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a structural schematic view of a mobile target coating device provided by an embodiment of the present disclosure;

FIG. 2 is a structural schematic view of a mobile target coating device provided by another embodiment of the present disclosure;

FIG. 3 is a top view of the target source and the infrared heating section of a mobile target coating device provided by an embodiment of the present disclosure;

FIG. 4 is a top view of the target source and the infrared heating section of a mobile target coating device provided by another embodiment of the present disclosure; and

FIG. 5 is a structural schematic view of the infrared heating radiating sheet and the rotating motor of a mobile target coating device provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which arc used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Organic optoelectronic devices, such as thin film transistors (TFTs), light emitting diodes (LEDs) and photovoltaic (PV) batteries, have drawn considerable attention among researchers in the past decade. Organic semiconductors can be deposited on a variety of substrates, which, when compared to inorganic semiconductors, will potentially simplify manufacturing and reduce costs. Despite the above advantages, organic semiconductors have unique processing requirements which may also limit their application. For example, a light emitting device and a photovoltaic cell (PV) battery are typically obtained from a film of conjugated polymers or monomers sandwiched between conductive electrodes. For full-color displays and multi-transistor circuits, the active organic layer itself also must be horizontally patterned. However, a typical organic layer is too brittle and therefore is impossible to withstand conventional semiconductor processing methods, such as photolithography, plasma processing, reactive ion etching or the like. Therefore, the researchers have developed a number of manufacturing and patterning techniques to adapt to the unique properties of organic materials, these technologies mainly emphasize the ease of processing and reduction of costs.

In the preparation of organic light emitting devices, the use of mobile targets for coating is a way to improve the target utilization rate. However, in the existing methods, the change in the crystallization temperature of a thin film leads to deterioration of the uniformity of the film formation. An embodiment of present disclosure uses an infrared heating section and an infrared temperature detecting section in combination, can ensure that the surface temperature of the moving target source is stable, and no temperature anomalies occur during the entire coating process, thus ensuring the uniformity of the coated film.

An embodiment of the present disclosure provides a mobile target coating device, which comprises a target source, a target source carrier section, an infrared temperature detecting section for detecting the surface temperature of the target source, an infrared heating section for heating the target source, and a control section. The target source carrier section carries the target source and can drive the target source to move, and for driving the target source to move, for example, the target source carrier section carries the target source and both make a synchronized motion; the infrared temperature detecting section and the infrared heating section are in signal communication with the control section, the control section receives detection signals from the infrared temperature detecting section and determines whether the temperature of the surface of the target source is uniform, when the control section determines that the temperature of a portion of the surface of the target source is lower than the temperature of other portions and the temperature difference value exceeds a pre-set value, the control section controls the infrared heating section to heat the surface of the target source at the portion having a lower temperature, and to stop heating when the surface temperature of the target source is uniform.

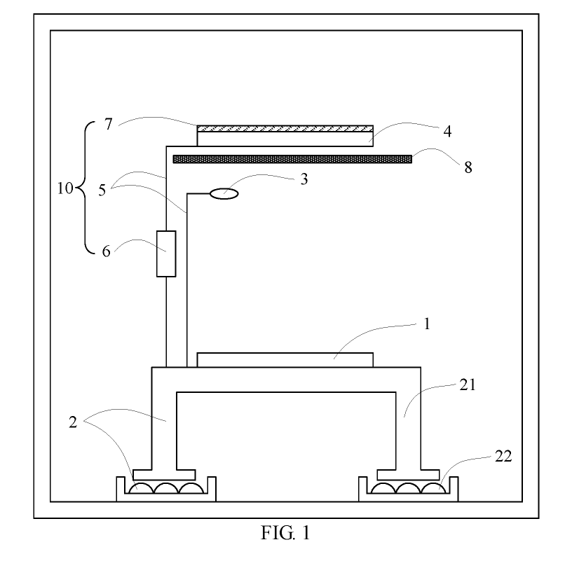

FIG. 1 is a schematic view of a mobile target coating device provided by an embodiment of the present disclosure. As illustrated in the drawing, the mobile target coating device comprises a target source 1, a target source carrier section 2, an infrared temperature detecting section 3 for detecting the surface temperature of the target source, an infrared heating section 4 for heating the target source, and a control section 10. The control section 10 may comprise a signal connecting portion 5 and a signal processing section 6; in one example, the control section 10 may further comprise an actuation section 7.

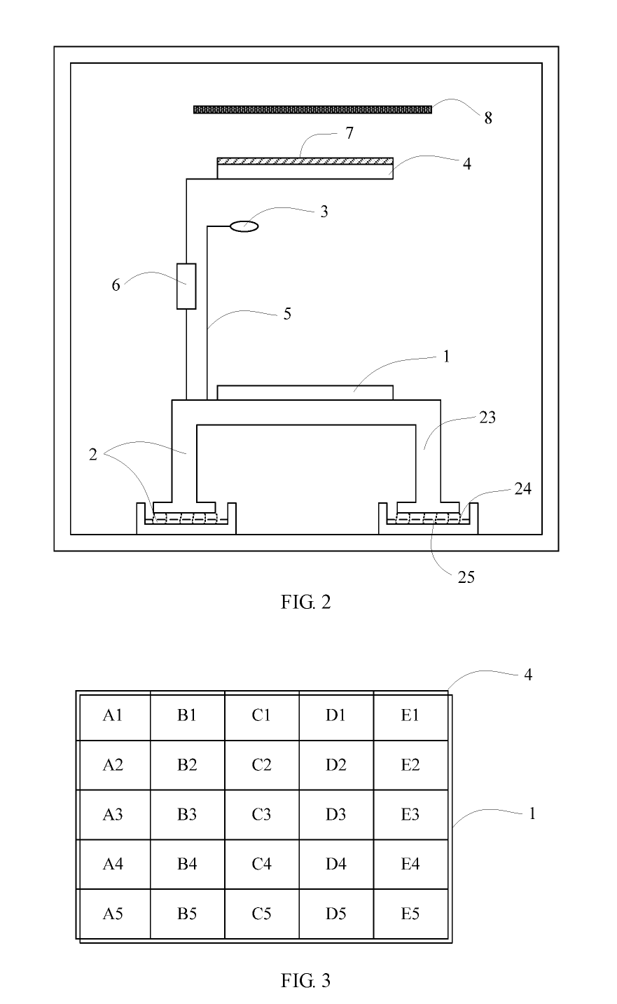

The target source carrier section 2 can carry the target source 1 on its carrying surface, and can drive the target source 1 to move freely in three dimensional directions within the inner space of the mobile target coating device, for example. In the embodiment as illustrated in the drawing, the substrate 8 to be coated is provided between the target source 1 and the infrared heating section 4, and is located in parallel with the target source 1. The size of the substrate 8 is generally greater than or equal to the size of the target source 1. In other examples, for example, as illustrated in FIG. 2, the infrared heating section 4 is provided between the substrate 8 to be coated and the target source 1, as long as the infrared heating section does not block the substance sputtered out from the target source 1 from depositing onto the substrate 8 to be coated.

This mobile target coating device can use two manners in the process of conducting coating operation. In the first manner, the target source 1 is fixed at a position to coat the substrate 8 located at the corresponding position, after the film thickness of the substrate 8 at the corresponding position reaches the pre-set thickness, the target source carrier section 2 drives the target source 1 to move to another position and continue to repeat the above process. In the second manner, the target source carrier section 2 drives the target source 1 to move continuously so as to make a scanning-style coating operation to different positions of the substrate 8. The power for driving the target source carrier section 2 may be, for example, from a stepping motor, and the driving mechanism may further comprise guide rails, screw rods, gears and so on.

The target source carrier section 2 may employ a low resistance track. For example, as illustrated in FIG. 1, the target source carrier section 2 comprises a magnetic levitation (maglev) track 22 and a target source support member 21. When the target source 1 needs to be moved, an electromagnetic repulsive force will be generated between the maglev track 22 and the target source support member 21 so as to hold up the target source support member 21 into a suspended state. In this state, the target source support member 21 can be driven to move in the x-axis and/or y-axis direction. The target source support member 21 is configured so as to be movable up and down, for example, by screw rods, or by pinion and rack, and so on.

FIG. 2 is a schematic view of a mobile target coating device provided by another embodiment of the present disclosure. As compared with the embodiment illustrated in FIG. 1, the target source carrier section 2 of this embodiment as illustrated in FIG. 2 comprises an air-cushion track 24 and a target source support member 23, and the air-cushion track 24 is provided with a plurality of air holes 25 facing the target source support member 23; when the target source 1 needs to moved, the plurality of air holes 25 on the air-cushion track 24 eject high-speed gas flows to hold up the target source support member 23 into the suspended state. In this state, the target source support member 23 can be driven to move in the x-axis and/or y-axis direction. The target source support member 23 is provided so as to movable up and down, for example, by screw rods, or by pinion and rack, and so on.

The running speed and acceleration of the target source carrier section 2 are parameters that affect the operating efficiency of the target source carrier section 2; faster running speed and greater acceleration can effectively reduce the time of a single move. Because the target source support member 21/23 is separated from the maglev track 22 or air-cushion track 24, the running speed is effectively improved. Also, in the embodiments of FIGS. 1 and 2. the target source carrier section 2 is subjected to a small friction force during movement, and therefore the speed of the target source carrier section 2 is more easily to be increased. In contrast, an existing common target source carrying system suffers from a large track resistance, and in the case where the tasks of transporting the target source become more arduous, the target source carrying system itself encounters frequent shutdown, and at this moment, too fast speed and excessive acceleration speeds up the worn-out of the parts thereof. However, the maglev track system or the air-cushion track system employed in the embodiments of present disclosure can overcome this disadvantage. Due to the separation of the track from the target source support member in the maglev track system or the air-cushion track system, it is possible to eliminate the mechanical friction, depress noise and reduce the mechanical wear of the parts.

For example, the infrared temperature detecting section 3 and the infrared heating section 4 may be connected to the target source carrier section 2, and in this case, when the target source carrier section 2 is moved, the infrared temperature detecting section 3 and the infrared heating section 4 move in synchronism with the target source carrier section 2. This arrangement can ensure that the infrared temperature detecting section 3 can accurately detect the surface temperature of the target source 1, and ensure that the infrared heating section 4 accurately heat a specific position of the surface of the target source 1. Undoubtedly, the infrared temperature detecting section 3 and the infrared heating section 4 can also be provided separately from the target source carrier section 2, and in this case, when the target source carrier section 2 is moved, the infrared temperature detecting section 3 and the infrared heating section 4 move in synchronism with the target source carrier section, or alternatively, the detecting angle, heating angle or the like is adjusted correspondingly.

The signal connecting portion 5 is connects (couples) the infrared temperature detecting section 3 and the signal processing section 6. The signal connecting portion 5 also connects (couples) the signal processing section 6 and the actuation section 7. The signal connecting portion 5 may transmit, for example, electrical signals or optical signals, for example, can be embodied as wires or fibers etc. The signal connecting portion 5 transfers the information about the surface temperature of the target source 1 detected by the infrared temperature detecting section 3 to the signal processing section 6, the signal processing section 6 processes this temperature information and then the signal connecting portion 5 sends a instruction information of the signal processing section 6 to the actuation section 7, so the actuation section 7 may control/drive the infrared heating section 4.

The signal processing section 6 determines whether the temperature of the surface of the target source 1 is uniform or not according to the detection result received from the infrared temperature detecting section 3. When the signal processing section 6 determines that the temperature at a certain portion of the surface of the target source 1 is lower than the temperatures of other portions and the temperature difference value exceeds a pre-set value, the signal processing section 6 issues an instruction to the actuation section 7, the actuation section 7 controls the infrared heating section 4 to heat the surface of the target source at the portion having a lower temperature until the temperature of the surface of the target source 1 become uniform and stop heating. The above pre-set value for the temperature difference may be selected according to the actually required accuracy, for example, 5° C., 1° C., 0.5° C., 0.1° C. The judgment criteria regarding whether the temperature of the surface of the target source is uniform or not may also be set according to a practical requirement. For example, it may be set that, when the temperature difference among individual portions of the surface of the target source is less than 5° C., 1° C., 0.5° C. or 0.1° C., the surface temperature of the target source is considered to be uniform.

For example, the target source 1 has an essentially flat target source surface, the infrared heating section 4 may also have an essentially flat infrared heating section surface, and in this case, the target source surface and the infrared heating section surface may be disposed parallel with each other; the normal projections of the target source and the infrared heating section onto the same plane (for example, the plane where the target source is located, or the plane where the infrared heating section is located, or the plane where the substrate is located) at least partially overlap with each other, or alternatively, the normal projection of the infrared heating section and the target source on the same plane at least partially overlap; the infrared temperature detecting section 3 is arranged between the surface of the target source 1 and the surface of the infrared heating section 4.

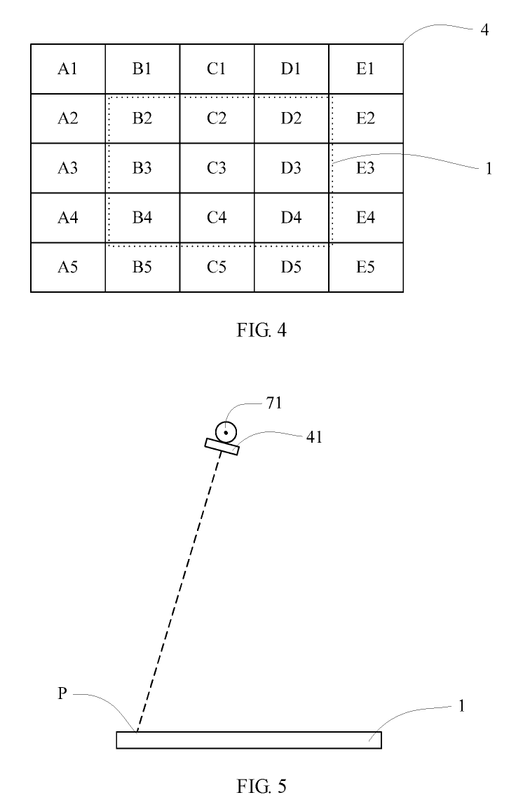

For example, the area size of the target source 1 is less than or equal to the area size of the infrared heating section 4. FIGS. 3 and 4 illustrate a top view of the target source 1 and the infrared heating section 4. As illustrated in FIG. 3, the area size of the target source 1 and the area size of the infrared heating section 4 are equal to each other, and they are disposed facing each other. Therefore, the target source 1 and the infrared heating section 4 overlap in the top view. As illustrated in FIG. 4, the area size of the target source 1 is less than the area size of the infrared heating section 4, and are disposed facing each other. Therefore, the target source 1 is within the range of the infrared heating section 4 in the top view.

For example, the infrared heating section 4 comprises a plurality of infrared heating radiating sheets. As illustrated in FIGS. 3 and 4, the infrared heating section 4 comprises 25 infrared heating radiating sheets Al-E5 in total, but the present disclosure is not limited to the shape and arrangement of the infrared heating radiating sheets as illustrated. When the signal processing section 6 determines that the temperature at a certain portion of the surface of the target source 1 is lower than the temperature of other portions and the temperature difference value exceeds the pre-set value, the signal processing section 6 issues an instruction to the actuation section 7, the actuation section 7 actuates the infrared heating radiating sheet(s) opposite to the surface of the target source at the portion having the lower temperature to heat the surface of the portion of the target source 1 having the lower temperature until the temperature of the surface of the target source 1 becomes uniform and then stop heating. For example, the signal processing section 6 detects that the temperature of the target source 1 at its upper left corner is lower than the temperature of other portions and the temperature difference value exceeds the pre-set value, as illustrated in FIG. 3, then issues an instruction to the actuation section 7, the actuation section 7 actuates the infrared heating radiating sheet(s) opposite to the upper left corner of the target source 1, i.e., the infrared heating radiating sheet Al so as to heat the upper left corner of the target source until the temperature of the surface of the target source becomes uniform and then stop heating. In one example, the surface of each of the infrared heating radiating sheets of the infrared heating section 4 may further be provided a radiation converging structure (for example, lens or reflecting part), so it is possible to perform heating to the local position of the target source 1.

For example, as illustrated in FIG. 5, the infrared heating section 4 may also comprise an infrared heating radiating sheet 41, the actuation section 7 comprises a rotating motor 71, the infrared heating radiating sheet 41 is connected with the rotating motor 71, and the signal processing section 6 is configured to determine whether the temperature of the surface of the target source is uniform or not; when the signal processing section 6 determines that a certain portion P of the target source surface has a temperature lower than the temperature of other portions, and the temperature difference value exceeds the pre-set value, the signal processing section 6 issues an instruction to the actuation section 7, the rotating motor 71 controls the infrared heating radiating sheet 41 connected therewith to turn on so as to heat the partial target source surface P having the lower temperature until the temperature of the surface of the target source becomes uniform and stop heating.

In the above embodiment, it is also possible to provide, for example, a fan or the like to cooperate with the infrared heating section 4 so as to facilitate the uniformity of the temperature.

For example, the surface of the target source 1 may be in a unity. Alternatively, the surface of the target source 1 may also be composed of a plurality of discrete sub-target sources; still for example, these sub-target sources are arranged on an annular driving belt so that it is possible to use these sub-target sources in turn, thus further ensuring the uniformity of the deposition.

As illustrated in FIGS. 1 and 2, for example, the target source 1 may be provided in parallel to the ground, and the infrared heating section 4 may be located above the target source 1. Alternatively, the infrared heating section 4 may be provided in parallel to the ground, and the target source 1 may be located above the infrared heating section 4. Still alternatively, the target source 1 and the infrared heating section 4 are all provided perpendicular to the ground.

For example, the infrared temperature detecting section 3 comprises an infrared camera or the like.

For example, the signal processing section 6 comprises a central processing unit (CPU), an image processing unit (GPU), a digital signal processor (DSP), a programmable logic controller or the like, and if required, may further comprise a memory, an input/output unit (e.g., a display, a touch screen, a touch pad, a keyboard, a cursor mouse and the like), or the like.

For example, the actuation section 7 comprises relays, drive electrodes, and the like.

The mobile target coating device of the embodiments of the present disclosure may be applied to various coating manners, including but not limited to magnetron sputtering method, vacuum vapor deposition method, and the like. Such a mobile target coating device is also suitable for the preparation of various material films, such as anode films, including but not limited to indium tin oxide film (ITO), zinc oxide tin film (IZO), and the like. In the mobile target coating device provided by the embodiments of the present disclosure, the infrared temperature detecting section detects the surface temperature of the target source 1 in real time, and the infrared heating section 4 heats duly the portion of the surface of the target source 1 having a lower temperature according to the detected temperature distribution information, thus ensuring uniform surface temperature of the target source 1 in the process of coating, and it is possible to obtain an anode film in which the resistance distribution is uniform over the entire plate. In one embodiment of the present disclosure, the resistivity of the anode film reaches up to 2×10⁻⁴Ω/cm, and its transmittance reaches up to 90% or more; the efficiency of operation and the product quality of the anode film are all enormously improved; the production cost is saved, and the service life thereof is extended by 2 times or above, and it results in energy-saving and environmental friendly.

What are described above is related to the illustrative embodiments of the disclosure only and not limitative to the scope of the disclosure; the scopes of the disclosure are defined by the accompanying claims.

The application claims priority to the Chinese patent application No. 201610053369.8, filed Jan. 26, 2016, the entire disclosure of which is incorporated herein by reference as part of the present application.

1. A mobile target coating device, comprising:
a target source;
a target source carrier section configured to carry and drive the target source to move;
an infrared temperature detecting section configured to detect a temperature of a surface of the target source;
an infrared heating section configured to heat the target source; and
a control section configured to receive a detection signal of the infrared temperature detecting section and determine whether the temperature of the surface of the target source is uniform or not;
wherein the control section is further configured to control the infrared heating section to heat a portion having a lower temperature of the surface of the target source and to stop heating after the temperature of the surface of the target source becomes uniform.

2. The mobile target coating device according to claim 1, wherein the infrared temperature detecting section and the infrared heating section are connected to the target source carrier section, and the infrared temperature detecting section and the infrared heating section can move in synchronism with the target source carrier section.

3. The mobile target coating device according to claim 1, wherein the surface of the target source is essentially parallel to a surface of the infrared heating section;
normal projections of the target source and the infrared heating section on a same plane at least partially overlap with each other.

4. The mobile target coating device according to claim 3, wherein an area size of the target source is less than or equal to an area size of the infrared heating section.

5. The mobile target coating device according to claim 1, wherein the infrared temperature detecting section is located between the surface of the target source and a surface of the infrared heating section.

6. The mobile target coating device according to claim 1, wherein the surface of the target source is in a unity.

7. The mobile target coating device according to claim 1, wherein the surface of the target source is composed of a plurality of discrete sub-target sources.

8. The mobile target coating device according to claim 7, wherein the plurality of discrete sub-target sources are arranged in an annular arrangement.

9. The mobile target coating device according to claim 1, wherein the infrared heating section comprises a plurality of infrared heating radiating sheets,
the control section is further configured to, in a case where the control section determines that a temperature of a portion of the surface of the target source is lower than a temperature of other portions and a temperature difference value exceeds a pre-set value, actuate an infrared heating radiating sheet or infrared heating radiating sheets opposite to the surface of the target source at the portion having the lower temperature, and to heat the surface of the target source at the portion having the lower temperature until the temperature of the surface of the target source becomes uniform and stop heating.

10. The mobile target coating device according to claim 9, wherein each of the infrared heating radiating sheets comprises a radiation converging structure.

11. The mobile target coating device according to claim 1, wherein the infrared heating section comprises one infrared heating radiating sheet, in a case where the control section determines that a temperature of a portion of the surface of the target source is lower than a temperature of other portions and a temperature difference value exceeds a pre-set value, the control section controls the infrared heating radiating sheet to turn on and heat the surface of the target source at the portion having the lower temperature until the temperature of the surface of the target source becomes uniform and stop heating.

12. The mobile target coating device according to claim 1, wherein the target source carrier section comprises a guide rail and a target source support member, and the target source support member is configured to move on the guide rail when the target source is required to move.

13. The mobile target coating device according to claim 12, wherein the guide rail is a maglev track, and the maglev track and the target source support member are configured to generate an electromagnetic repulsive force therebetween so as to hold up the target source support member into a suspended state.

14. The mobile target coating device according to claim 12, wherein the guide rail comprises an air-cushion track on which a plurality of air holes are provided facing the target source support member, the plurality of air holes on the air-cushion track are configured to eject high-speed gas flows so as to hold up the target source support member into a suspended state.

15. The mobile target coating device according to claim 1, wherein the target source and the infrared heating section are arranged essentially parallel to a ground.

16. The mobile target coating device according to claim 1, wherein the infrared heating section is arranged above the target source.

17. (canceled)

18. The mobile target coating device according to claim 1, wherein the target source is arranged above the target source.

19. The mobile target coating device according to claim 1, wherein the target source and the infrared heating section are arranged essentially perpendicular to a ground.

20. The mobile target coating device according to claim 1, wherein the infrared temperature detecting section comprises an infrared camera.

21. A coating method using a mobile target coating device, the mobile target coating device comprising a target source, a target source carrier section, an infrared temperature detecting section for detecting a temperature of a surface of the target source, an infrared heating section for heating the target source, and a control section, wherein the target source carrier section carries the target source and can drive the target source to move freely in three dimensional directions, and the infrared temperature detecting section and the infrared heating section are in signal communication with the control section,
the method comprising:
the control section receiving a detection signal from the infrared temperature detecting section, and determining whether the temperature of the surface of the target source is uniform or not;
in a case where the control section determines that a temperature of a portion of the surface of the target source is lower than a temperature of other portions and a temperature difference value exceeds a pre-set value, the control section controls the infrared heating section to heat the surface of the target source at the portion having the lower temperature until the temperature of the surface of the target source becomes uniform and stop heating.
